(19) United States
(12) Patent Application Publication
(10) Pub. No.: US 2004/0101013 A1
(43) Pub. Date: May 27, 2004

(54) Semiconductor laser device and method of manufacturing the same

(75) Inventor: Makoto Yokota, Mihara-Shi (JP)

Correspondence Address: MORRISON & FOERSTER LLP, 755 PAGE MILL RD, PALO ALTO, CA, 94304-1018, US

(73) Assignee: SHARP KABUSHIKI KAISHA, Osaka-Shi (JP)

(21) Appl. No.: 10/645,698

(22) Filed: Aug. 20, 2003

(30) Foreign Application Priority Data
Aug. 20, 2002 (JP) 2002-239053
Jun. 2, 2003 (JP) 2003-156802

(51) Int. Cl. H01S 5/00

(52) U.S. Cl. 372/49

(57) ABSTRACT

A semiconductor laser device has a silicon oxide film formed so as to be in contact with at least one end of a semiconductor laser crystal as an end face protection film for a semiconductor laser element. For example, the semiconductor laser device has a silicon oxide film formed so as to be in contact with a main emission face side of a laser chip. Such a silicon oxide film preferably has an index of refraction not smaller than 1.6. Another film may be formed outside the silicon oxide film. The silicon oxide film is preferably formed with resistance heating vapor deposition. Thus, a semiconductor laser device which is provided with an end face protection film, and can avoid COD level lowering and attain high reliability of a laser element, as well as a method of manufacturing the same can be provided.

### BACKGROUND OF THE INVENTION

1. Field of the Invention

The present invention relates to a semiconductor laser device employing a protection film with high reliability on an end face, and a method of manufacturing the same.

2. Description of the Background Art

FIG. 7 schematically shows a representative, conventional semiconductor laser device. As shown in FIG. 7, a number of conventional semiconductor laser devices include an alumina (Al₂O₃) film 100h and an alumina film 101h of the same reflectivity on a main emission face side (front face side) 1a and a back face side 1b of a laser chip 1 including a laser chip active layer 2, respectively.

FIG. 8 schematically shows a conventional high-power semiconductor laser device attaining light output of not smaller than 20 mW. As shown in FIG. 8, in general, in order to enhance light output Pf from the main emission face (front face), the semiconductor laser device is designed such that main emission face side 1a attains low reflection smaller than a reflectivity when a protection film is not provided, and back face side 1b attains high reflection larger than a reflectivity when the protection film is not provided.

For example, reflectivity of alumina film 100h on main emission face side 1a is set approximately to not larger than 17%, and a film thickness corresponding to this reflectivity is approximately 67 to 177 nm. Meanwhile, even if a film having an index of refraction larger than that of laser chip 1 is used as a back face side protection film 101 on back face side 1b, only one layer is not sufficient to attain high reflectivity. Therefore, an alumina film 101b having a thickness of λ/4 (λ represents laser oscillation wavelength) and serving as a protection film in a first layer and a third layer, and an amorphous silicon film 101c having a thickness of λ/4 and serving as a protection film in a second layer and a fourth layer are alternately provided. Finally, an alumina film 101d of a thickness of λ/2 is provided as a fifth layer. In this manner, a protection film attaining high reflectivity of approximately not smaller than 85% can be formed.

A series of process steps for forming a protection film attaining a reflectivity as described above on a light-emitting end face from cleavage of a semiconductor laser chip will now be described in the following. FIGS. 10A, 10B, 11 and 12 illustrate a method of forming a protection film in a semiconductor laser device.

As shown in FIGS. 10A and 10B, a cleavage line 11 is formed by scribing in a direction orthogonal to a light-emitting portion (channel) 10 between an electrode 4 of a specific element and an electrode 44 of an adjacent element on a semiconductor laser wafer 3 where p and n electrodes 4, 5 are formed. Thereafter, as shown in FIG. 11, semiconductor laser wafer 3 is divided into laser bars (a laser chip like a bar) 12 by cleavage. Then, as shown in FIG. 12, laser bar 12 is set in a laser bar fixing apparatus 13 so that electrode faces thereof are superposed. Here, all laser bars 12 are set such that main emission face sides 1a and back face sides 1b thereof face in the same direction respectively. Then, a protection film having a prescribed reflectivity is formed on a light-emitting end face of laser bar 12 fixed to laser bar fixing apparatus 13. In this case, a vacuum deposition apparatus is generally used.

When the end face protection film for the laser chip is formed with vapor deposition, partial pressure of oxygen molecules generated by decomposition of alumina which is a material of the protection film is raised immediately after the start of vapor deposition. If the oxygen collides with or is bonded to the laser end face, the laser end face is likely to suffer damage therefrom. In addition, the laser chip active layer and a layer in the vicinity thereof have a composition containing aluminum atoms, the damage may further be aggravated. When such semiconductor laser is operated with high power, required reliability may not be obtained.

FIG. 9 schematically shows another conventional high-power semiconductor laser device. In FIG. 9, in order to improve reliability of high-power type laser, a silicon film 100i is formed as a protection film for light-emitting end face prior to vapor deposition of alumina. In such a case, as silicon film 100i attaining improved heat dissipation and causing no oxygen generation due to decomposition of a material in vapor deposition is formed in advance, a film forming can be achieved in the vicinity of the end face of the laser bar immediately after the start of vapor deposition in a state in which partial pressure of the oxygen is low, thereby suppressing damage in the vicinity of the end face as described above.

In addition, in order to prevent adverse effect on laser oscillation property due to generation of leakage current in silicon film 100i, a technique disclosed in Japanese Patent Laying-Open No. 2002-164609 has set a thickness of the silicon film to not larger than 4 nm (preferably, 0.5 to 3 nm).

On the other hand, if silicon film 100i is formed on main emission face side 1a of laser chip 1 as shown in FIG. 9, light absorption takes place on silicon film 100i, and lowering of COD level (characteristic level against the Catastrophic Optical Damage) due to variation in the thickness of the silicon film may occur.

Moreover, as shown in FIG. 13, in some cases, Au used in electrode 5 reacts with Si in silicon film 100i, and accordingly, Au 6 that reacted with Si may diffuse in the end face of main emission face side 1a. If Au 6 that reacted with Si is present beyond a light-emitting point 2a, leakage current due to the diffused Au is likely, which may adversely affect the oscillation property of the laser element. Further, electron beam (EB) vapor deposition may damage a terminal, to cause lowering in the COD level.

### SUMMARY OF THE INVENTION

In a semiconductor laser device according to one aspect of the present invention, a silicon oxide film formed so as to be in contact with at least one end of a semiconductor laser element crystal is provided as an end face protection film for a semiconductor laser element. As silicon oxide has an extinction coefficient of laser beam lower than that of a silicon film, lowering of the COD level due to variation in film thickness is unlikely. In addition, as silicon oxide is unlikely to react with an Au electrode, leakage current is unlikely, whereby oscillation property of a laser element is not adversely affected. Further, when silicon oxide is employed, an amount of oxygen generated in vapor deposition is smaller than in a case in which alumina is employed. Therefore, damage to the laser end face is small, and reliability of the laser element can be improved.

Preferably, the silicon oxide has an index of refraction of not smaller than 1.6. The silicon oxide is of various chemical compositions such as SiO₂, SiO or the like. The smaller an amount of contained oxygen is, the greater the index of refraction will be. In other words, oxygen permeability is lowered, and an amount of oxygen generated in vapor deposition is made smaller. For example, SiO₂ has an index of refraction of approximately 1.49, whereas SiO has an index of refraction of approximately 1.7. Any silicon oxide of a chemical composition attaining an index of refraction not smaller than 1.6 will be able to sufficiently suppress generation of oxygen in vapor deposition.

Preferably, another film is formed outside the silicon oxide film. This is because reliability of a laser element can be improved by the silicon oxide film which is present inside, and because a wide variety of optical designs are allowed by another film present on the outside.

Any film protecting the laser end face and transmitting laser may be used as another film, without limited to a material such as silicon oxide or silicon alumina. Preferably, however, an alumina which is optically transparent to a wavelength of emitted light and has high insulation and thermal resistance is used.

Preferably, the silicon oxide film placed inside has a film thickness of 0.5 nm to 20 nm. If the film thickness is smaller than 0.5 nm, the laser end face may be damaged in forming the outside film. On the other hand, if the film thickness is larger than 20 nm, lowering of COD level or lowering of laser output due to increase in laser light absorption in the film may be caused.

Preferably, the main emission face has a reflectivity of 6% to 17%, and the back face has a reflectivity of not smaller than 85%. In order to improve laser beam output Pf from the main emission face, reflectivity on the main emission face is designed to be small, and reflectivity on the back face is designed to be large. In this manner, an amount of light emitted to the back face side can be decreased, and an amount of light emitted to the main emission face side can be increased. If the reflectivity on the emission face is too small, a problem may arise by noise due to return light.

Here, the reflectivity on a main reflection face can be set to a value in a further optimal range within a range of 6% to 17%, in accordance with the laser oscillation wavelength, considering light output and a driving current. For example, when the laser oscillation wavelength is set to 720 nm to 810 nm, the reflectivity of the main reflection face is further preferably set to a value within a range of 11% to 17%. When the laser oscillation wavelength is set to 620 nm to 720 nm, the reflectivity of the main reflection face is further preferably set to a value within a range of 6% to 11%.

In a method of manufacturing a semiconductor laser device according to another aspect of the present invention, the silicon oxide film is formed with resistance heating vapor deposition. Resistance heating vapor deposition represents one type of vacuum deposition, in which Joule heat is generated by a resistance heating unit (heater) by a current flow therein, to heat and evaporate a vapor deposition material so as to form a film on a substrate. In addition to resistance heating vapor deposition, other examples of vacuum deposition include electron beam heating vapor deposition in which a vapor deposition material is irradiated with an electron beam to heat and evaporate the same so as to form a film on a substrate, and induction heating vapor deposition in which a vapor deposition material is heated and evaporated by high-frequency induction to form a film on a substrate. Though these methods may be employed, resistance heating is preferable because damage to the substrate in forming the film is minimized.

In a method of manufacturing a semiconductor laser device according to yet another aspect of the present invention, the silicon oxide film and another film are formed in a single chamber. When two layers are formed successively in a single chamber, a time period for film forming will be reduced. In addition, as the surface of a first layer is not contaminated, excellent adhesion between the first layer and a second layer can be attained.

As described above, according to the present invention, a silicon oxide film formed so as to be in contact with at least one end of a semiconductor laser element crystal is provided as an end face protection film for a semiconductor laser element. In this manner, an extinction coefficient of a laser beam can be made smaller, and lowering of the COD level due to variation in the film thickness can be suppressed. In addition, as diffusion of Au to a light-emitting end face is prevented, leakage current in the vicinity of the laser end face is suppressed, and oscillation property of the laser element is not adversely affected. Further, as an amount of oxygen generated in vapor deposition is small, the laser end face is not seriously damaged, and reliability of the laser element can be improved.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 schematically shows one embodiment of a semiconductor laser device according to the present invention.

FIG. 2 shows change in reflectivity with respect to thickness of a silicon oxide film when laser oscillation wavelength is set to 780 nm in one embodiment.

FIG. 3 schematically shows another embodiment of a semiconductor laser device according to the present invention.

FIG. 4 shows change in reflectivity with respect to total thickness of a silicon oxide film and an alumina film when laser oscillation wavelength is set to 780 nm in another embodiment.

FIG. 5 schematically shows yet another embodiment of a semiconductor laser device according to the present invention.

FIG. 6 shows change in reflectivity with respect to total thickness of a silicon oxide film and an alumina film when laser oscillation wavelength is set to 650 nm in yet another embodiment.

FIG. 7 schematically shows a representative, conventional semiconductor laser device.

FIG. 8 schematically shows one conventional high-power semiconductor laser device.

FIG. 9 schematically shows another conventional high-power semiconductor laser device.

FIG. 10A illustrates a method of forming a protection film in the semiconductor laser device.

FIG. 10B is an enlarged view of a portion represented with reference numeral 20 in FIG. 10A.

FIG. 11 illustrates the method of forming the protection film, following FIG. 10A.

FIG. 12 illustrates the method of forming the protection film, following FIG. 11.

FIG. 13 illustrates diffusion of Au to a main emission face side due to reaction of a silicon film and an Au electrode.

### DESCRIPTION OF THE PREFERRED EMBODIMENTS

### First Embodiment

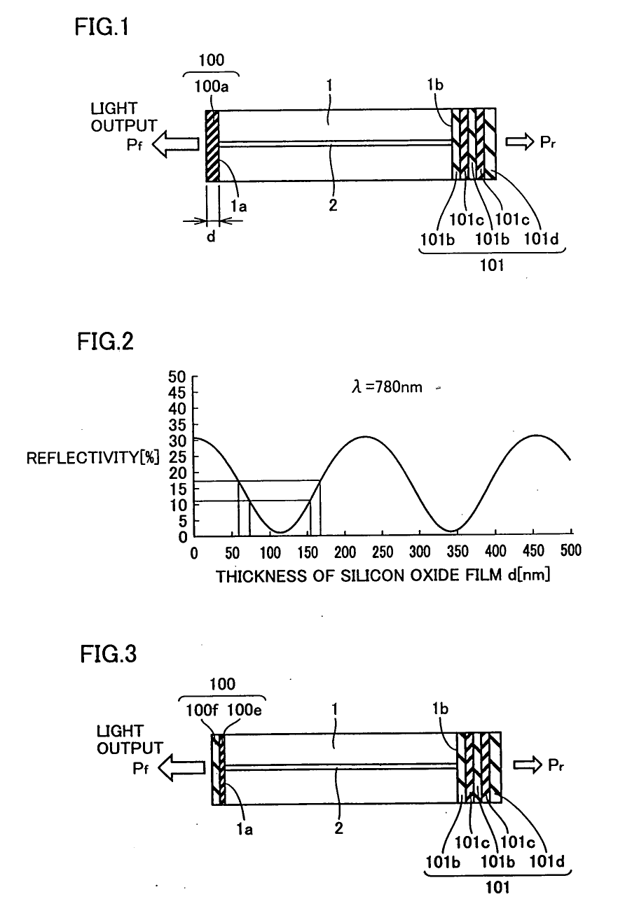

In the following, specific embodiments of a semiconductor laser device according to the present invention will be described with reference to the drawings. In a semiconductor laser device in one embodiment of the present invention, as shown in FIG. 1, a silicon oxide film 100a is provided as main emission face side protection film 100 on main emission face side 1a of laser chip 1. On back face side 1b of laser chip 1, a multi-layer high-reflection film constituted of five layers, that is, alumina films 101b serving as the first and third layers, amorphous silicon films 101c serving as the second and fourth layers, and alumina film 101d serving as the fifth layer, is formed as back face side protection film 101.

The semiconductor laser device in the present embodiment is fabricated in the following manner. Initially, as shown in FIG. 12, laser bar 12 is set in laser bar fixing apparatus 13 so that electrode faces are superposed. Here, all laser bars 12 are set such that main emission face sides 1a and back face sides 1b thereof face in the same direction respectively. Then, silicon oxide film 100a is formed as main emission face side protection film 100 on main emission face side 1a of laser bar 12 fixed to laser bar fixing apparatus 13. A film forming speed is set to 0.01 nm/s to 0.5 nm/s, and a substrate temperature in film forming is set to 250° C. to 300° C.

FIG. 2 shows change in reflectivity with respect to thickness of a silicon oxide film when laser oscillation wavelength is set to 780 nm in the present embodiment. When oxide silicon film 100a has an index of refraction of 1.70, and laser chip active layer 2 has an index of refraction of 3.50, the reflectivity of silicon oxide film 100a is varied in accordance with change in film thickness d thereof, as shown in FIG. 2. As can be seen from FIG. 2, in order to attain the reflectivity of main emission face side 1a of 11% to 17% with respect to laser oscillation wavelength of 780 nm, thickness of the silicon oxide film is set to 62 nm to 75 nm or 154 nm to 168 nm.

Referring to FIG. 12, after a film is formed on main emission face side 1a, laser bar fixing apparatus 13 is turned around by 180°. Then, as shown in FIG. 1, alumina film 101b, amorphous silicon film 101c, alumina film 101b, and amorphous silicon film 101c each having a thickness of λ/4, and alumina film 101d having a thickness of λ/2 are successively formed as multi-layer high-reflection back face side protection film 101, on back face side 1b of laser chip 1.

### Second Embodiment

In a semiconductor laser device in another embodiment of the present invention, as shown in FIG. 3, a silicon oxide film 100e of a thickness of 10 nm serving as a first layer and an alumina film 100f serving as a second layer are provided as main emission face side protection film 100 on main emission face side 1a of laser chip 1. On back face side 1b of laser chip 1, a multi-layer high-reflection film as in the first embodiment is formed as back face side protection film 101.

The semiconductor laser device in the present embodiment is fabricated in a manner the same as in the first embodiment. After laser bar 12 is fixed to laser bar fixing apparatus 13, silicon oxide film 100e (10 nm in thickness) and alumina film 100f are successively formed on main emission face side 1a of fixed laser bar 12 as main emission face side protection film 100.

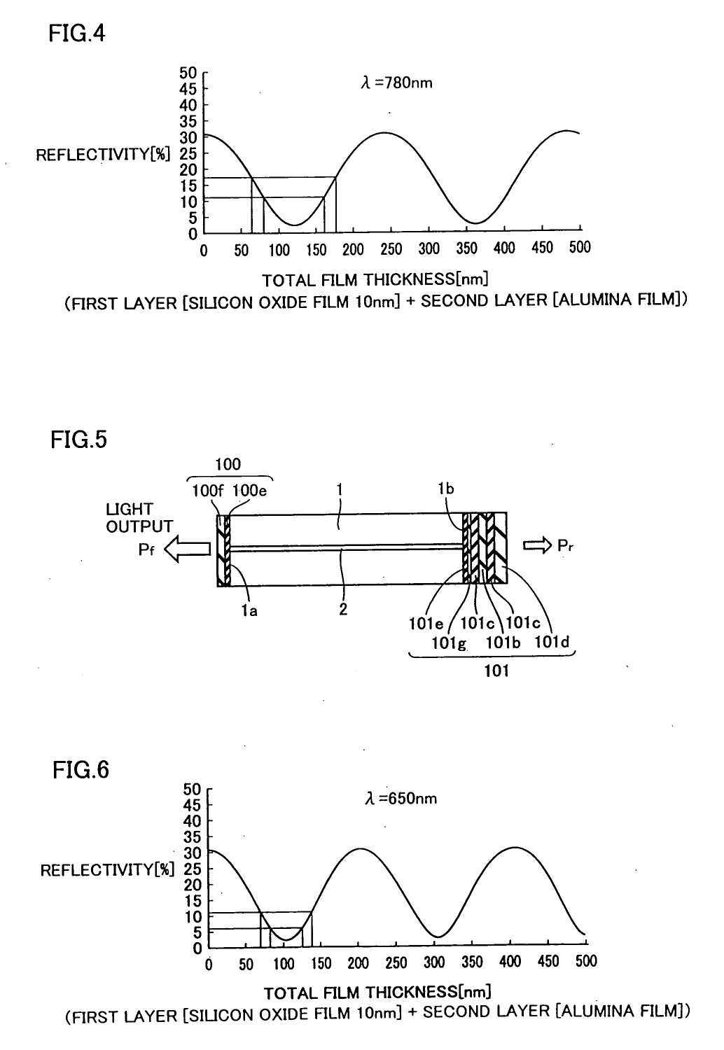

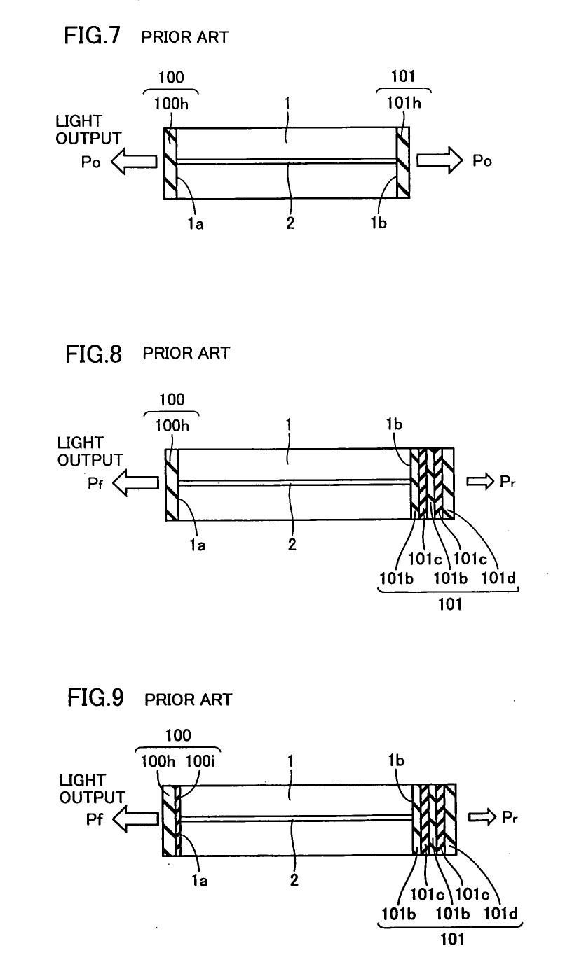

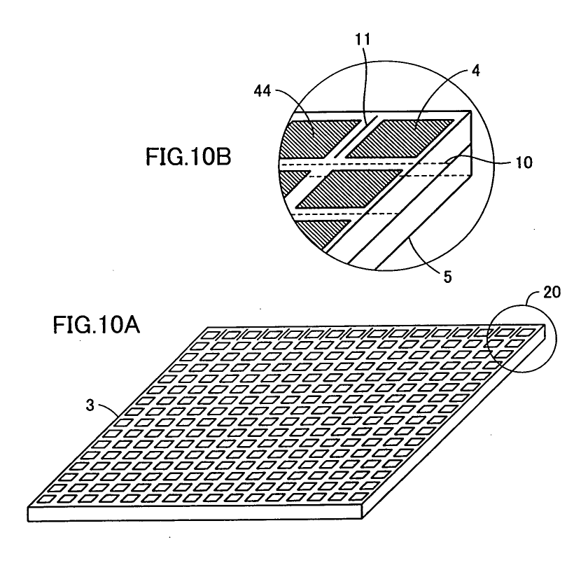

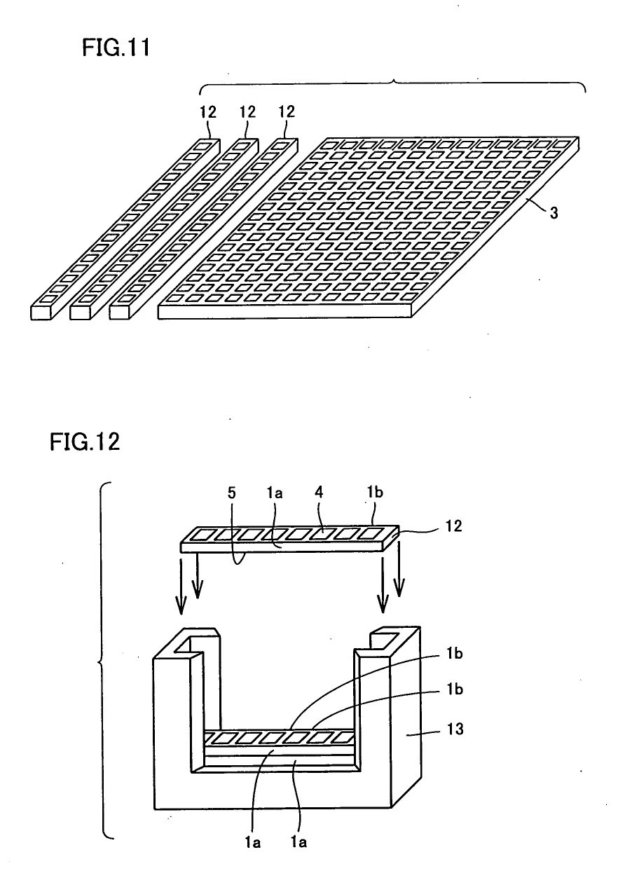

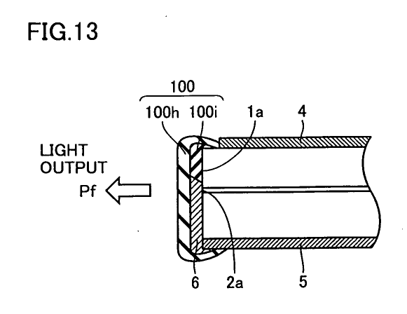

FIG. 4 shows change in reflectivity with respect to total thickness of a silicon oxide film and an alumina film when laser oscillation wavelength is set to 780 nm in the present embodiment. When the reflectivity of silicon oxide film 100e, alumina film 100f, and laser chip active layer 2 is set to 1.70, 1.60 and 3.50 respectively, the reflectivity of main emission face side protection film 100 is varied in accordance with the change of the total film thickness of silicon oxide film 100e and alumina film 100f, as shown in FIG. 4. Therefore, in order to attain the reflectivity of main emission face side 1a of 11% to 17% with respect to laser oscillation wavelength of 780 nm, thickness of alumina film 100f is set to 67 nm to 82 nm or 162 nm to 177 nm.

### Third Embodiment

In a semiconductor laser device in yet another embodiment of the present invention, as shown in FIG. 5, a film constituted of two layers similar to that in the second embodiment is provided as main emission face side protection film 100 on main emission face side 1a of laser chip 1. On back face side 1b of laser chip 1, a multi-layer high-reflection film constituted of silicon oxide film 101e having a thickness of 10 nm serving as a first layer and an alumina film 101g serving as a second layer instead of alumina film 101b in the first layer in the first embodiment, amorphous silicon 101c serving as third and fifth layers, alumina film 101b serving as a fourth layer, and alumina film 101d serving as a sixth layer is formed as back face side protection film 101.

Fabrication of the semiconductor laser device in the present embodiment is described with reference to FIG. 12. As in the first embodiment, after a film is formed on main emission face side 1a, laser bar fixing apparatus 13 is turned around by 180°. Then, as shown in FIG. 5, silicon oxide film 101e (10 nm in thickness) serving as the first layer and alumina film 101g successively formed thereon are formed as multi-layer high-reflection back face side protection film 101 on back face side 1b of laser chip 1. The sum of thickness of two films is set to λ/4 so as to minimize the reflectivity of the silicon oxide film in the first layer and the alumina film in the second layer. When the laser oscillation wavelength is set to 780 nm, and when the reflectivity of silicon oxide film 101e and alumina film 101g is set to 1.7 and 1.6 respectively, thickness of alumina film 101g is set to 110 nm. Further on back face side 1b, amorphous silicon film 101c, alumina film 101b, and amorphous silicon film 101c each having a thickness of λ/4, and alumina film 101d having a thickness of λ/2 are successively formed.

### Fourth Embodiment

The present embodiment shows an example in which the laser oscillation wavelength is set to 650 nm in a semiconductor laser device with a configuration similar to that in the third embodiment shown in FIG. 5. In the semiconductor laser device in the present embodiment, silicon oxide film 100e of a thickness of 10 nm serving as the first layer and alumina film 100f serving as the second layer are provided as main emission face side protection film 100 on main emission face side 1a of laser chip 1, as in the second and the third embodiments. On back face side 1b of laser chip 1, a multi-layer high-reflection film as in the third embodiment is provided as back face side protection film 101.

FIG. 6 shows change in reflectivity with respect to total thickness of a silicon oxide film and an alumina film when laser oscillation wavelength is set to 650 nm in the present embodiment. When the reflectivity of silicon oxide film 100e, alumina film 100f, and laser chip active layer 2 is set to 1.70, 1.60 and 3.50 respectively, the reflectivity of main emission face side protection film 100 is varied in accordance with the change of the total film thickness of silicon oxide film 100e and alumina film 100f, as shown in FIG. 6. Therefore, in order to attain the reflectivity of main emission face side 1a of 6% to 11% with respect to laser oscillation wavelength of 650 nm, a thickness of alumina film 100f is set to 60 nm to 71 nm or 113 nm to 124 nm.

The semiconductor laser element in the present embodiment is fabricated in the following manner, as in the second and third embodiments. Silicon oxide film 100e (10 nm in thickness) and alumina film 100f successively formed thereon are formed as main emission face side protection film 100 on main emission face side 1a. Referring to FIG. 12, after a film is formed on main emission face side 1a, laser bar fixing apparatus 13 is turned around by 180°. Then, as shown in FIG. 5, silicon oxide film 101e (10 nm in thickness) serving as the first layer and alumina film 101g successively formed thereon are formed as multi-layer high-reflection back face side protection film 101 on back face side 1b of laser chip 1. The sum of thickness of two films is set to λ/4 so as to minimize the reflectivity of the silicon oxide film in the first layer and the alumina film in the second layer. When the laser oscillation wavelength is set to 650 nm, and when the reflectivity of silicon oxide film 101e and alumina film 101g is set to 1.7 and 1.6 respectively, film thickness of alumina film 101g is set to 90 nm. Further on back face side 1b, amorphous silicon film 101c, alumina film 101b, and amorphous silicon film 101c each having a thickness of λ/4, and alumina film 101d having a thickness of λ/2 are successively formed, as in the third embodiment.

Here, not only alumina but also SiNₓ, SiO₂, TiO₂ or the like may be used as a stable film formed on the silicon oxide film. Moreover, the first layer on the back face side may effectively be a silicon oxide film.

Although the present invention has been described and illustrated in detail, it is clearly understood that the same is by way of illustration and example only and is not to be taken by way of Imitation, the spirit and scope of the present invention being limited only by the terms of the appended claims.

What is claimed is:

1. A semiconductor laser device, wherein
a silicon oxide film is formed so as to be in contact with at least one end of a semiconductor laser element crystal as an end face protection film for a semiconductor laser element.

2. The semiconductor laser device according to claim 1, wherein
silicon oxide forming said silicon oxide film has an index of refraction of at least 1.6.

3. The semiconductor laser device according to claim 1, wherein
a main emission face of said semiconductor laser element has a reflectivity of 6% to 17%, and a back face thereof has a reflectivity of at least 85%.

4. The semiconductor laser device according to claim 1, wherein
another film is formed outside said silicon oxide film.

5. The semiconductor laser device according to claim 4, wherein
alumina is used as a material for forming another film.

6. The semiconductor laser device according to claim 4, wherein
said silicon oxide film has a film thickness of 0.5 nm to 20 nm.

7. A method of manufacturing a semiconductor laser device having
a silicon oxide film formed so as to be in contact with at least one end of a semiconductor laser element crystal and another film formed outside said silicon oxide film, wherein
said silicon oxide film and another film are formed in a single chamber.

8. A method of manufacturing a semiconductor laser device having
a silicon oxide film formed so as to be in contact with at least one end of a semiconductor laser element crystal, wherein
said silicon oxide film is formed by resistance heating vapor deposition.
